(19) United States
(12) Patent Application Publication
(10) Pub. No.: US 2026/0367152 A1
(43) Pub. Date: Nov. 19, 2026

(54) DEVICE AND METHOD FOR DIAGNOSING BATTERY CELLS, AND A VEHICLE INCLUDING SAME

(71) Applicants: HYUNDAI MOTOR COMPANY, Seoul (KR); KIA CORPORATION, Seoul (KR)

(72) Inventors: Si Joong Kim, Hwaseong-si (KR); Hyun Jun Jo, Hwaseong-si (KR); Hyun Jun Jang, Hwaseong-si (KR); Tae Kyu Kang, Hwaseong-si (KR)

(73) Assignees: HYUNDAI MOTOR COMPANY, Seoul (KR); KIA CORPORATION, Seoul (KR)

(21) Appl. No.: 19/323,147

(22) Filed: Sep. 9, 2025

(30) Foreign Application Priority Data
May 19, 2025 (KR) 10-2025-0064795

(51) Int. Cl. G01R 31/367; B60L 58/16; G01R 31/3835; G01R 31/396; H01M 10/42; H01M 10/48

(52) U.S. Cl. CPC G01R 31/367; B60L 58/16; G01R 31/3835; G01R 31/396; H01M 10/4285; H01M 10/482; H01M 2220/20

(57) ABSTRACT

A device for diagnosing battery cells includes a controller configured to, based on whether voltages of a plurality of cells included in a battery are within a preset voltage range in a charge cycle of the battery, determine a current cell-specific relative index. The current cell-specific relative index is a relative change amount of an incremental capacity analysis value of each of the cells corresponding to the voltage range. The controller is further configured to determine whether each cell is abnormal based on cumulative cell-specific relative indices including the current cell-specific relative index. The device further includes an output device configured to output data regarding whether each cell is abnormal.

### CROSS-REFERENCE TO THE RELATED APPLICATION

This application claims the benefit of and priority to Korean Patent Application No. 10-2025-0064795, filed on May 19, 2025 in the Korean Intellectual Property Office, the entire contents of which are incorporated herein by reference.

### TECHNICAL FIELD

The present disclosure relates to a battery cell diagnostic device and a battery cell diagnostic method for determining whether each cell is abnormal based on electrochemical characteristic data acquired during multiple battery cell charging processes. The present disclosure also relates to a vehicle including the device.

### BACKGROUND

A battery mounted on a means of transportation such as an electric vehicle may include a plurality of battery cells in which electric energy is stored, and research is actively being conducted on a battery cell diagnostic device for more precisely diagnosing deterioration or abnormality of such battery cells.

For example, a battery cell diagnostic device may measure cell status information such as a voltage, a current, and a temperature from each battery cell included in a battery. The battery cell diagnostic device may perform control such as charge/discharge control, abnormality determination, and cell balancing for maintaining voltage balance between cells based on the cell status information.

The matters described as the background technology above are only for the purpose of enhancing understanding of the background of the present disclosure and do not acknowledge that they correspond to prior art already known to a person with ordinary skill in the art.

### SUMMARY

Therefore, the present disclosure has been made in view of the above problems. An aspect of the present disclosure aims to provide a battery cell diagnostic device and a battery cell diagnostic method for determining whether each cell is abnormal based on electrochemical characteristic data acquired during multiple battery cell charging processes. The present disclosure also aims to provide a vehicle including the device.

Another aspect of the present disclosure aims to provide a battery cell diagnostic device and a battery cell diagnostic method capable of determining whether each cell is abnormal even when only some of a plurality of preset voltage ranges have been passed during a charging process. The present disclosure also aims to provide a vehicle including the device.

The aspects to be achieved in the present disclosure are not limited to the aspects mentioned above. Other aspects that are not mentioned can be clearly understood by a person having ordinary skill in the art to which the present disclosure belongs from the present disclosure.

In accordance with an aspect of the present disclosure, a device for diagnosing battery cells includes a controller configured to, based on whether voltages of a plurality of cells included in a battery are within a preset voltage range in a charge cycle of the battery, determine a current cell-specific relative index. The current cell-specific relative index is a relative change amount of an incremental capacity analysis value of each of the cells corresponding to the voltage range. The controller is further configured to determine whether each cell is abnormal based on cumulative cell-specific relative indices including the current cell-specific relative index. The device for diagnosing battery cells further includes an output device configured to output data regarding whether each cell is abnormal to the outside.

According to an embodiment, the controller may further determine the current cell-specific relative index based on i) an average of change amounts of incremental capacity analysis values of the cells and the ii) change amounts of the incremental capacity analysis values of the cells in the voltage range.

According to an embodiment, the controller may further determine whether each cell is abnormal based on a slope of a cell-specific trend line determined based on the cumulative cell-specific relative indices.

According to an embodiment, the controller may further determine a cell corresponding to the current cell-specific relative index as abnormal based on a sign of a value obtained by subtracting a previous cell-specific relative index determined at a time point adjacent to a time point, when the current cell-specific relative index is determined, from the current cell-specific relative index remaining constant for a preset number of times.

According to an embodiment, the controller may further determine a cell corresponding to the current cell-specific relative index as an abnormal cell due to capacity deviation or leakage current based on the sign of the value being continuously positive for a preset number of times.

According to an embodiment, the controller may further determine a cell corresponding to the current cell-specific relative index as an abnormal cell in which capacity deterioration progresses based on the sign of the value being continuously negative for a preset number of times.

According to an embodiment, the controller may further determine whether a cell corresponding to the current cell-specific relative index is abnormal based on whether the value monotonically decreases or monotonically increases.

According to an embodiment, the controller may further determine a cell corresponding to the current cell-specific relative index as an abnormal cell in which deterioration is accelerated based on the value determined as monotonically decreasing or monotonically increasing.

According to an embodiment, the controller may further determine whether each cell is abnormal based on a Mahalanobis distance of the cumulative cell-specific relative indices.

According to an embodiment, the controller may further generate a plurality of data distributions with different charging cycles serving as a basis of the Mahalanobis distance among a plurality of charging cycles considered in determining the cumulative cell-specific relative indices.

The controller may further determine the Mahalanobis distance for each of the data distributions.

According to an embodiment, the controller may further determine a cell corresponding to cumulative cell-specific relative indices based on a number of pieces of data exceeding the Mahalanobis distance being equal to or greater than a preset threshold number as an abnormal cell.

According to an embodiment, the controller may further determine whether each cell is abnormal based on i) a previous cell-specific relative index determined at a time point adjacent to a time point when the current cell-specific relative index is determined in the cumulative cell-specific relative indices and ii) the current cell-specific relative index.

According to an embodiment, the controller may further determine a threshold based on an average change amount of the cumulative cell-specific relative indices. The controller may further determine whether a cell corresponding to the current cell-specific relative index is abnormal based on whether a value obtained by subtracting the previous cell-specific relative index from the current cell-specific relative index exceeding the threshold.

According to an embodiment, the controller may further determine an abnormality score based on a weight corresponding to each of a plurality of algorithms for determining abnormality and a number of pieces of data determined to be abnormal based on the plurality of algorithms. The controller may further determine abnormality based on the abnormality score.

According to an embodiment, the preset voltage range may be set to a plurality of ranges set including different voltages at peak values of the incremental capacity analysis values. The controller may further determine the current cell-specific relative index corresponding to at least one range based on the voltages of the cells being within the at least one of the plurality of ranges in the charging cycle.

In accordance with another aspect of the present disclosure, a method of diagnosing battery cells includes, based on whether voltages of a plurality of cells included in a battery are within a preset voltage range in a charge cycle of the battery, determining, by a controller, a current cell-specific relative index. The current cell-specific relative index is a relative change amount of an incremental capacity analysis value of each of the cells corresponding to the voltage range. The method of diagnosing battery cells further includes determining, by the controller, whether each cell is abnormal based on cumulative cell-specific relative indices including the current cell-specific relative index.

The method of diagnosing battery cells further includes outputting data regarding whether each cell is abnormal to the outside by an output device.

According to an embodiment, determining whether each cell is abnormal may include determining, by the controller, whether each cell is abnormal based on i) a previous cell-specific relative index determined at a time point adjacent to a time point when the current cell-specific relative index is determined in the cumulative cell-specific relative indices and ii) the current cell-specific relative index.

According to an embodiment, determining whether each cell is abnormal may include determining, by the controller, a cell corresponding to the current cell-specific relative index as abnormal based on a sign of a value obtained by subtracting a previous cell-specific relative index determined at a time point, adjacent to a time point when the current cell-specific relative index is determined, from the current cell-specific relative index remaining constant for a preset number of times.

According to an embodiment, determining whether each cell is abnormal may include determining, by the controller, whether each cell is abnormal based on a Mahalanobis distance of the cumulative cell-specific relative indices.

In accordance with another aspect of the present disclosure, a vehicle includes a battery including a plurality of cells and includes a controller. The controller is configured to, based on whether voltages of a plurality of cells included in a battery are within a preset voltage range in a charge cycle of the battery, determine a current cell-specific relative index. The current cell-specific relative index is a relative change amount of an incremental capacity analysis value of each of the cells corresponding to the voltage range. The controller is further configured to determine whether each cell is abnormal based on cumulative cell-specific relative indices including the current cell-specific relative index. The vehicle further includes an output device configured to output data regarding whether each cell is abnormal to the outside.

### BRIEF DESCRIPTION OF THE DRAWINGS

The above and other aspects, features, and advantages of the present disclosure should be more clearly understood from the following detailed description taken in conjunction with the accompanying drawings, in which:

FIG. 1 illustrates a battery and a battery cell diagnostic device according to an embodiment;

FIGS. 2, 3, 4, and 5 illustrate a charging profile and cumulative relative indices for each cell corresponding to first to third ranges according to an embodiment;

FIGS. 6 and 7 illustrate a plurality of ranges and changes in incremental capacity analysis values according to an embodiment;

FIG. 8 is a graph for describing a process in which a controller according to an embodiment compares cumulative relative indices for cells;

FIGS. 9 and 10 are graphs for describing a process in which the controller according to an embodiment compares slopes of trend lines;

FIG. 11 is a graph for describing a process in which the controller according to an embodiment determines whether a failure has occurred based on whether a slope is continuous or monotonic;

FIGS. 12, 13, 14, and 15 are graphs for describing a process in which the controller according to an embodiment determines whether there is an abnormality based on a Mahalanobis distance; and

FIG. 16 is a flowchart illustrating a method of diagnosing abnormality for each battery cell according to an embodiment.

### DETAILED DESCRIPTION

In describing the embodiments disclosed in the present disclosure, a detailed description of known functions and configurations incorporated herein has been omitted when it may obscure the gist of the embodiments of the present disclosure. In addition, the attached drawings are only intended to facilitate easy understanding of the embodiments of the present disclosure, and the technical ideas disclosed in the present disclosure are not limited by the attached drawings. It should be understood that the attached drawings include all modifications, equivalents, or substitutes included in the spirit and scope of the present disclosure. The following disclosure is not intended to limit the present disclosure to the described form or a specific field, and it is contemplated that various alternative aspects and modifications to the present disclosure are possible, whether explicitly described or implied in the present disclosure. Those having ordinary skill in the art to which the present disclosure pertains should recognize that the form and details of the present disclosure may be changed.

The present disclosure is described with reference to specific aspects. However, as should be understood by those having ordinary skill in the art to which the present disclosure pertains, various embodiments of the present disclosure may be modified or implemented in various other ways without departing from the spirit and scope of the present disclosure. Accordingly, the following description should be considered illustrative and is intended to teach those having ordinary skill in the art to make and use the various embodiments. It should be understood that the forms in which the present disclosure is illustrated and described herein should be taken as representative embodiments. Equivalent elements, materials, processes, or steps may be substituted for those exemplified and described herein. The words “including”, “comprising”, “incorporating”, “consisting of”, “have”, “is”, and the like, used in describing the present disclosure, should be construed in a non-exclusive manner, i.e., to allow for other items, components, or elements not explicitly listed therein to be represented. Additionally, reference to the singular should be construed to include the plural.

Furthermore, the various embodiments disclosed herein are to be taken in an illustrative and explanatory sense and should not be construed as limiting the scope of the present disclosure. Any references (e.g., attached, affixed, coupled, connected, etc.) are used solely to aid understanding of the present disclosure and do not imply limitations as to the location, orientation, or use of a configuration or method disclosed herein. Accordingly, if the references exist, they should be interpreted broadly. Moreover, such references do not imply that two or more elements are directly connected to one another. Additionally, any numeric terms, such as “first”, “second”, “third”, “primary”, “secondary”, “main” or any other general term or numeric term, should be taken only as identifiers to aid in understanding the various components, forms, variations or modifications of the present disclosure, and do not imply any limitation on any component, form, variation or modification or order or preference thereof. In other words, these terms may be used to describe various components, but the components are not limited by the terms. The terms are used only for the purpose of distinguishing one component from another.

The suffixes “module” and “part” used for components in the following description are given or used interchangeably solely for the convenience of writing the specification and do not have a distinct meaning or role.

When a component is referred to as being “coupled” or “connected” to another component, it should be understood that the component may be directly coupled or connected to the other component, and there may also be other components therebetween. On the other hand, when it is said that a component is “directly coupled” or “directly connected” to another component, it should be understood that there are no other components therebetween.

In addition, a unit or a control unit included in a name is a term widely used in naming a controller that controls a specific function of a vehicle, and the unit or the control unit does not mean a generic functional unit.

The controller may include a communication device that communicates with other controllers or sensors to control the function thereof, a memory that stores an operating system or logic instructions and input/output information, and one or more processors that perform determination, computation, decisions, etc. necessary for controlling the functions thereof.

Any number of components or various components in any of the configurations may be included in the present disclosure. The components may include any combination of features described in the present disclosure and may be arranged in any of the various configurations described in the present disclosure. The concepts regarding the structure and arrangement of the components of the present disclosure as well as the use and operation of the components may be applied to any number of embodiments in any combination as well as to the specific embodiments discussed in the present disclosure. Embodiments including those having various features in various arrangements are described below with reference to the drawings.

Hereinafter, various embodiments of the present disclosure are described in detail with reference to the attached drawings. Regardless of the drawing numerals, identical or similar components are given the same reference numerals and redundant descriptions thereof have been omitted. When a controller, module, component, device, element, or the like of the present disclosure is described as having a purpose or performing an operation, function, or the like, the controller, module, component, device, element, or the like should be considered herein as being “configured to” meet that purpose or to perform that operation or function. Each controller, module, component, device, element, and the like may separately embody or be included with a processor and a memory, such as a non-transitory computer readable media, as part of the apparatus.

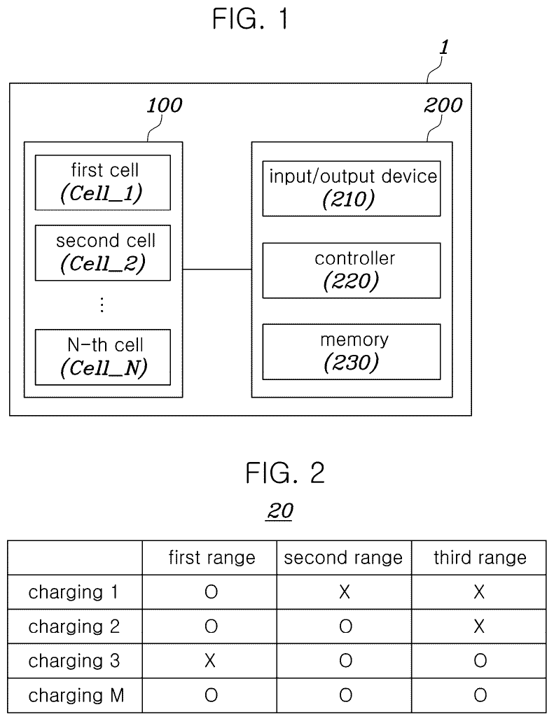

FIG. 1 illustrates a battery and a battery cell diagnostic device according to an embodiment.

Referring to FIG. 1, a vehicle 1 includes a battery 100 including a plurality of cells Cell_1, Cell_2, . . . , and Cell_N and a battery cell diagnostic device 200.

The battery 100 can store electric power and can perform charging and discharging of the stored electric power. For example, the battery 100 may be a battery pack including the plurality of cells Cell_1, Cell_2, . . . , and Cell_N.

The battery diagnostic device 200 may include an input/output device 210, a controller 220, and a memory 230 and may determine whether each of the cells Cell_1, Cell_2, . . . , and Cell_N is abnormal.

The input/output device 210 may obtain data from the battery 100 or may transmit determined abnormality information to an external device. For example, the input/output device 210 may include an input unit that acquires current data and voltage data of the battery 100 and transmits the same to the controller 220. The input/output device 210 may include an output unit that transmits information on abnormality determined by the controller 220 to an external device (e.g., an AVNT (Audio, Video, Navigation and Telematics) terminal (not shown) of the vehicle).

The controller 220 determines a current cell-specific relative index, which is a relative change amount of incremental capacity of each of the cells Cell_1, Cell_2, . . . , and Cell_N corresponding to a voltage range based on whether the voltages of the cells Cell_1, Cell_2, . . . , and Cell_N are within a preset voltage range during a charging process of the battery 100 including the cells cell 1, Cell_2, . . . , and Cell_N. The controller 220 determines whether each of the cells Cell_1, Cell_2, . . . , and Cell_N is abnormal based on cumulative cell-specific relative indices in which the current cell-specific relative index has been reflected.

Here, an incremental capacity analysis value is a value determined based on Incremental Capacity Analysis (ICA) or Differential Capacity Analysis (DCA). The incremental capacity analysis value may generally be represented as a differential value of capacity with respect to voltage change, for example, a dQ/dV value.

The current cell-specific relative index and the cumulative cell-specific relative indices are described in more detail with reference to FIGS. 2, 3, 4, and 5.

The memory 230 may store information necessary for the controller 220 to determine abnormality. For example, the memory 230 may store cumulative cell-specific relative indices corresponding to each of preset voltage ranges determined by the controller 220.

The battery cell diagnostic device 200 may be implemented as a battery management system (BMS) included in the vehicle 1, but this is merely an example and the battery cell diagnostic device 200 may be implemented using a controller different from the BMS.

Although the battery cell diagnostic device 200 is included in the vehicle 1 in the present embodiment, the battery cell diagnostic device 200 does not necessarily have to be equipped in the vehicle 1, and the battery cell diagnostic device 200 may be similarly applied to other systems or devices that require electric power storage and diagnosis.

Hereinafter, a cumulative cell-specific relative index and a current cell-specific relative index with respect to each of a plurality of voltage ranges are described with reference to FIGS. 2, 3, 4, and 5. FIGS. 2, 3, 4, and 5 illustrate a charging profile according to an embodiment and cumulative cell-specific relative indices with respect to first to third ranges.

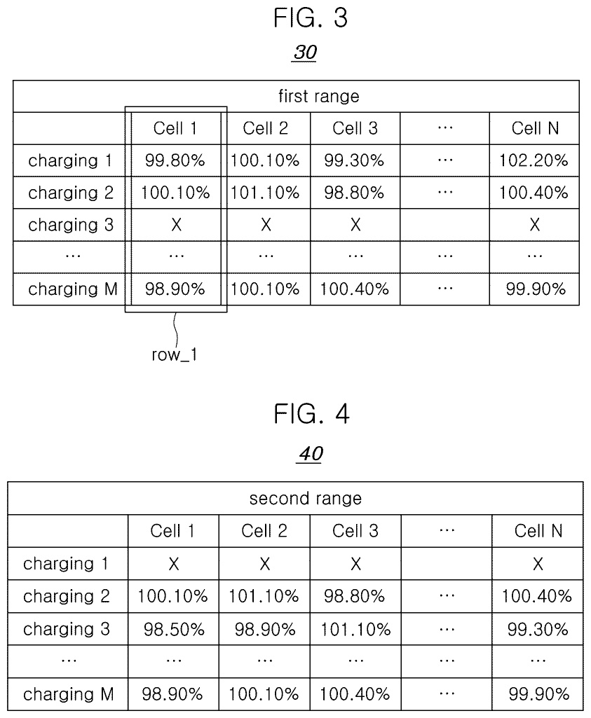

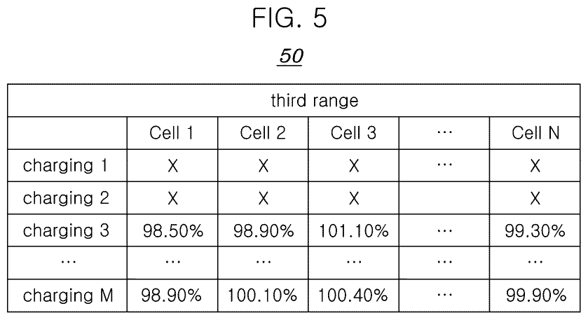

FIG. 2 shows a charging profile table 20 indicating whether the voltages of the plurality of cells are within the first range, the second range, and the third range during M charging processes. FIG. 3 shows a first table 30 indicating a plurality of cumulative cell-specific relative indices corresponding to the plurality of cells Cell_1, Cell_2, . . . , and Cell_N when the voltages of the cells are within the first range during the M charging processes. FIG. 4 shows a second table 40 indicating a plurality of cumulative cell-specific relative indices corresponding to the plurality of cells Cell_1, Cell_2, . . . , and Cell_N when the voltages thereof are within the second range during the M charging processes. FIG. 5 shows a third table 50 indicating a plurality of cumulative cell-specific relative indices corresponding to the plurality of cells Cell_1, Cell_2, . . . , and Cell_N when the voltages thereof are within the third range during the M charging processes.

A dQ/dV relative index may be determined based on the average of incremental capacity analysis values of the cells Cell_1, Cell_2, . . . , and Cell_N in a preset voltage range and the incremental capacity analysis values of the cells Cell_1, Cell_2, . . . , and Cell_N.

For example, the controller 220 may obtain a dQ/dV relative index based on the following mathematical expression 1. Here, DDQT represents the dQ/dV relative index, A represents the average of the incremental capacity analysis values of the cells Cell_1, Cell_2, . . . , and Cell_N for each range, and ai represents the incremental capacity analysis value of any battery cell.

$$DDQT = ( \frac{{a}_{1} - A}{A} \times 100 ) + 100 \qquad [ Mathematical expression 1 ]$$

The current cell-specific relative index may mean a dQ/dV relative index of each of the cells Cell_1, Cell_2, . . . , and Cell_N corresponding to a charging process of the battery 100 in at least one of a plurality of preset voltage ranges when the voltage of each cell is within the at least one voltage range during the charging process.

For example, if the voltage of each cell is within the preset first range, but is not within the second range and the third range in a first charging cycle of the battery 100, the current cell-specific relative index, which is the dQ/dV relative index of each of the cells Cell_1, Cell_2, . . . , and Cell_N in the first table 30 corresponding to the first range in the first charging cycle, may be updated. For example, because the voltage of each cell is not within the second range and the third range, the current cell-specific relative indices in the second table 40 corresponding to the second range and the third table 50 corresponding to the third range in the first charging cycle may not be updated.

Cumulative cell-specific relative indices may mean data in which dQ/dV relative indices obtained with respect to the plurality of cells Cell_1, Cell_2, . . . , and Cell_N are accumulated and stored for each charging cycle during multiple charging processes of the battery 100.

For example, in the first range, the cumulative cell-specific relative indices with respect to the first cell Cell_1 may correspond to the first row row_1 of the first table 30.

Hereinafter, a case in which the controller 220 determines abnormality based on a first cumulative cell-specific relative index, which is the cumulative cell-specific relative index of the first cell Cell_1 in the first range among a plurality of cumulative cell-specific relative indices, is described.

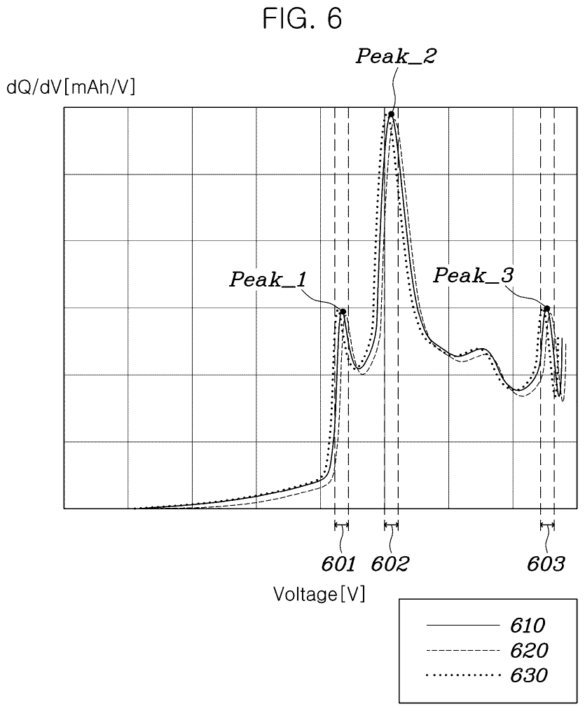

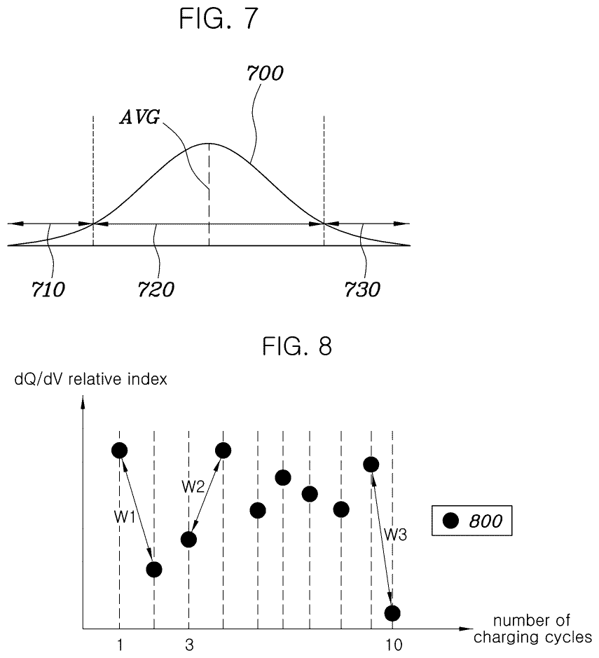

FIG. 6 and FIG. 7 illustrate a plurality of ranges and changes in incremental capacity analysis values according to an embodiment.

FIG. 6 shows a first range 601, which is a preset voltage range. FIG. 6 shows a second range 602, which is higher than the first range. FIG. 6 shows a third range 603, which is higher than the second range. FIG. 6 shows a first incremental capacity graph 610 showing change in an incremental capacity analysis value of a cell in a general situation. FIG. 6 shows a second incremental capacity graph 620 showing change in an incremental capacity analysis value of the cell when the separator of the cell is lithium plated. FIG. 6 shows a third incremental capacity graph 630 showing change in an incremental capacity analysis value of the cell when a micro-short-circuit has occurred.

The controller 220 may set a plurality of voltage ranges having different voltages in which incremental capacity analysis values have peak values as the voltages change.

For example, the controller 220 may set a voltage range including a cell-specific voltage at the first peak Peak_1 of the incremental capacity analysis value as the first range 601. The controller 220 may set a voltage range including a cell-specific voltage at the second peak Peak_2 of the incremental capacity analysis value as the second range 602. The controller 220 may set a voltage range including a cell-specific voltage at the third peak Peak_3 of the incremental capacity analysis value as the third range 603. According to an embodiment, the first to third ranges 601, 602, and 603 may correspond to different voltage ranges between 0 V and 5 V.

The controller 220 may determine whether each cell is abnormal based on differences in dQ/dV values in the preset voltage ranges.

For example, referring to the first to third ranges 601, 602, and 603 in the first incremental capacity graph 610 and the second incremental capacity graph 620, when lithium plating occurs on the separator of the cells, the dQ/dV values in the first to third ranges 601, 602, and 603 may decrease compared to the dQ/dV values at the same cell-specific voltage when compared to a normal cell. For example, the controller 220 can determine that the cell has deteriorated.

As another example, referring to the first incremental capacity graph 610 and the third incremental capacity graph 630, when a micro-short-circuit has occurred in the cell, the dQ/dV values in the first to third ranges 601, 602, and 603 may increase compared to the dQ/dV values at the same cell-specific voltage when compared to a normal cell. For example, the controller 220 can determine that the cell is abnormal due to capacity deviation or leakage current.

That is, the controller 220 can determine whether each cell is abnormal based on a dQ/dV relative index for relatively comparing an average dQ/dV value and a dQ/dV value of each cell.

FIG. 7 shows a graph 700 showing the standard deviation of the dQ/dV relative indices with respect to each of the plurality of cells Cell_1, Cell_2, . . . , and Cell_N, an average AVG of the dQ/dV relative indices with respect to each of the cells Cell_1, Cell_2, . . . , and Cell_N, a normal range 720, a first abnormal range 710, and a second abnormal range 730.

When the voltages of the cells are within at least one of the plurality of ranges during a charging process, the controller 220 may determine current cell-specific relative indices and cumulative cell-specific relative indices corresponding to the at least one range.

For example, when the voltages of the cells are within the first range 601, the controller 220 may determine the current cell-specific relative indices based on the average AVG of the dQ/dV relative indices of the cells Cell_1, Cell_2, . . . , and Cell_N in the first table 30 corresponding to the first range 601 and the dQ/dV relative indices of the cells Cell_1, Cell_2, . . . , and Cell_N.

The controller 220 may determine whether each cell is abnormal based on the current cell-specific relative index in a preset voltage range.

For example, if the difference between a cell-specific do/dV relative index and the average AVG of dQ/dV relative indices is equal to or greater than a preset threshold and the cell-specific dQ/dV relative index is located in the first abnormal range 710 and the second abnormal range 730, the controller 220 may determine the cell corresponding to the dQ/dV relative index as abnormal.

As another example, the controller 220 may count relative indices exceeding a first threshold (for example, 105%) among dQ/dV relative indices for each voltage range. The controller 220 may determine that a cell for which the counted number of dQ/dV relative indices exceeds a reference number among the plurality of cells Cell_1, Cell_2, . . . , and Cell_N is abnormal.

As another example, the controller 220 may determine an abnormality score based on a plurality of algorithms for determining abnormality and weights corresponding to the algorithms. The controller 220 may finally determine abnormality based on the determined abnormality score.

Hereinafter, a plurality of algorithms for determining abnormality is described with reference to FIGS. 8, 9, 10, 11, 12, 13, 14, and 15.

FIG. 8 is a graph for describing a process in which the controller according to an embodiment compares cumulative cell-specific relative indices.

FIG. 8 shows a first graph 800 in which cumulative cell-specific relative indices of the first cell Cell_1 corresponding to the first range are depicted in a scatter plot.

The controller 220 may determine whether each cell is abnormal based on a previous cell-specific relative index and the current cell-specific relative index. Here, the previous cell-specific relative index is a relative index determined at a time point adjacent to a time point when the current cell-specific relative index is determined. The previous cell-specific relative index corresponds to the dQ/dV relative index with respect to the cell in a charging cycle before the current cell-specific relative index is determined.

For example, if the value obtained by subtracting the previous cell-specific relative index from the current cell-specific relative index exceeds a threshold, the controller 220 may determine the cell corresponding to the current cell-specific relative index as abnormal.

Referring to the first graph 800, the first value W1, which is obtained by subtracting the previous cell-specific relative index from the current cell-specific relative index during the second charging process, the second value W2, which is obtained by subtracting the previous cell-specific relative index from the current cell-specific relative index during the third charging process, and the third value W3, which is obtained by subtracting the previous cell-specific relative index from the current cell-specific relative index during the tenth charging process, may be determined to exceed a threshold.

Here, the threshold may be determined based on the average change amount of cumulative cell-specific relative indices using the following mathematical expression 2. For example, Threshold represents the threshold, Mean represents the average of current cell-specific relative indices, and a represents a weight that reflects cell characteristics and vehicle characteristics.

Threshold=Mean*(100+α)% [Mathematical expression 2]

As another example, if the number of times the value obtained by subtracting the previous cell-specific relative index from the current cell-specific relative index exceeds the threshold during a preset number of cycles satisfies a count condition (e.g., three times), the controller 220 may determine the cell corresponding to the current cell-specific relative index as abnormal.

Referring to the first graph 800, if the preset number of cycles is ten and the count condition is three times, the controller 220 may determine the first cell Cell_1 corresponding to the current cell-specific relative index as abnormal during the tenth charging process in which the number of times the value obtained by subtracting the previous cell-specific relative index from the current cell-specific relative index exceeds the threshold is three.

That is, the controller 220 may determine whether each of the plurality of cells Cell_1, Cell_2, . . . , and Cell_N is abnormal based on whether abrupt change in the dQ/dV relative indices continuously occurs in a specific cell.

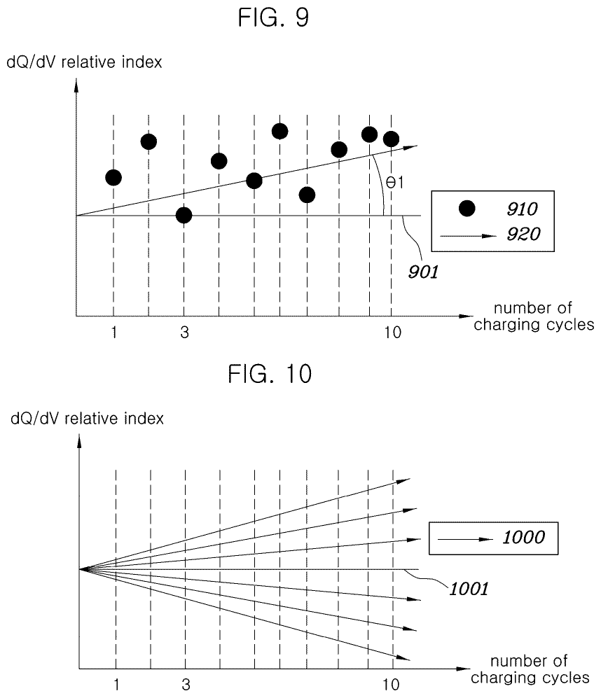

FIG. 9 and FIG. 10 are graphs for describing a process in which the controller according to an embodiment compares the slopes of trend lines.

FIG. 9 shows a first graph 910 in which first cumulative cell-specific relative indices are depicted in a scatter plot. FIG. 9 shows a first trend line graph 920 in which a trend line reference angle 901 and a trend of the first cumulative cell-specific relative indices are depicted in a linear function form. FIG. 10 shows a graph 1000 of a plurality of cell-specific trend lines, in which a trend line reference angle 1001 and cell-specific trend lines for a plurality of cells Cell_1, Cell_2, . . . , and Cell_N are depicted.

The controller 220 may determine whether each cell is abnormal based on the slopes of the cell-specific trend lines determined based on the cumulative cell-specific relative indices.

For example, if the slope of the trend line for a certain cell in the graph 1000 is greater or less than a value obtained by multiplying the average of trend line slopes of the cells Cell_1, Cell_2, . . . , Cell_N by a preset margin value, the controller 220 may determine the cell as an abnormal cell in which deterioration progresses faster than other cells.

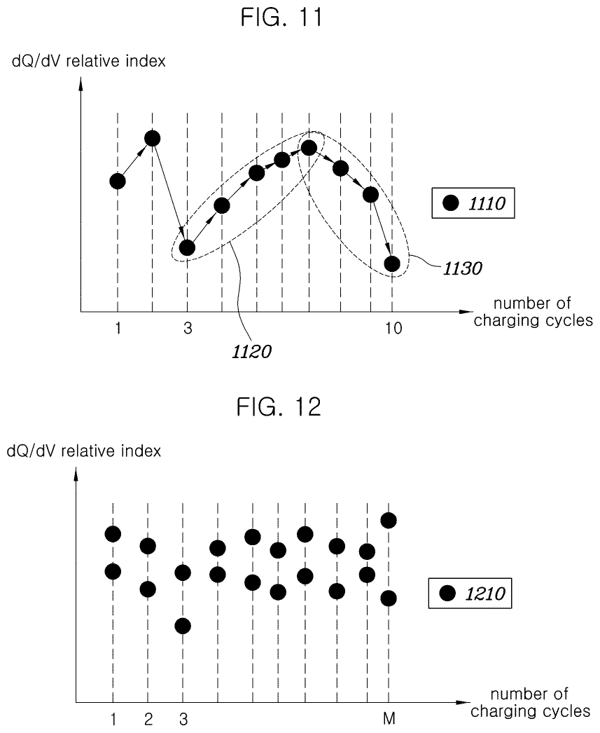

FIG. 11 is a graph for describing a process in which the controller according to an embodiment determines whether a failure has occurred based on whether a slope is continuous or monotonous.

Referring to FIG. 11, a first graph 1110 shows the cumulative cell-specific relative index of the first cell Cell_1 in the first range during ten charging processes. In an increasing section 1120, the cumulative cell-specific relative index continuously increases. In a decreasing section 1130, the cumulative cell-specific relative index monotonically decreases.

The controller 220 may determine a cell as abnormal when the sign of the value obtained by subtracting a previous cell-specific relative index determined at a time point adjacent to a determination time point of the current cell-specific relative index from the cell remains constant for a preset number of times (for example, three times).

For example, in the increasing section 1120 in which the sign of the value obtained by subtracting a previous cell-specific relative index from the current cell-specific relative index is positive three or more times in a row, the controller 220 may determine the first cell Cell_1 corresponding to the current cell-specific relative index to have abnormality due to capacity deviation or leakage current.

As another example, if the sign of the value obtained by subtracting a previous cell-specific relative index from the current cell-specific relative index is negative three or more times in a row, the controller 220 may determine the cell corresponding to the current cell-specific relative index as an abnormal cell in which capacity deterioration is in progress.

The controller 220 may determine whether the cell corresponding to the current cell-specific relative index is abnormal based on whether the value obtained by subtracting a previous cell-specific relative index from the current cell-specific relative index monotonically decreases or whether the value obtained by subtracting a previous cell-specific relative index from the current cell-specific relative index monotonically increases.

For example, the controller 220 may determine the cell corresponding to the current cell-specific relative index as an abnormal cell in which deterioration is accelerated in a monotonically decreasing section 1130. In the monotonically decreasing section 1130, the difference between the current cell-specific relative index and the previous cell-specific relative index gradually increases.

FIGS. 12, 13, 14, and 15 are graphs for describing a process in which the controller according to the embodiment determines abnormality based on the Mahalanobis distance.

FIG. 12 shows a graph 1210 in which a scatter plot of the cumulative cell-specific relative indices of all cells Cell_1, Cell_2, . . . , and Cell_N is illustrated.

The controller 220 may determine abnormality of a cell based on the Mahalanobis distance of cumulative cell-specific relative indices.

For example, the controller 220 may generate a plurality of data distributions with different charging cycles as a basis for the Mahalanobis distance, based on the cumulative cell-specific relative indices of the cells Cell_1, Cell_2, . . . , and Cell_N for a plurality of ranges. The controller 220 may determine the Mahalanobis distance for each of the data distributions. The controller 220 may determine a cell corresponding to a relative index exceeding the Mahalanobis distance as an abnormal cell.

For example, the controller 220 may set a data distribution corresponding to an M*N matrix having M charging cycles as columns and N cumulative cell-specific relative indices corresponding to each charging cycle as rows and may determine the Mahalanobis distance based on the following mathematical expression 3. Here, d_{M(x)} represents the Mahalanobis distance, x represents a data vector to be measured, Mean_{M,N} represents the mean vector of the data distribution, and COV_{M,N} represents the covariance matrix of the distribution.

d_{M(x)}=\sqrt{(x−Mean_{M,N})COV_{M,N}(x−Mean_{M,N})^{T}} [Mathematical expression 3]

The controller 220 may generate a plurality of data distributions with different charging cycles as the basis for the Mahalanobis distance and may determine the Mahalanobis distance for each of the data distributions.

In other words, the controller 220 can be set to generate a plurality of data distributions with different charging cycles corresponding to the value M of the mean vector of the distributions.

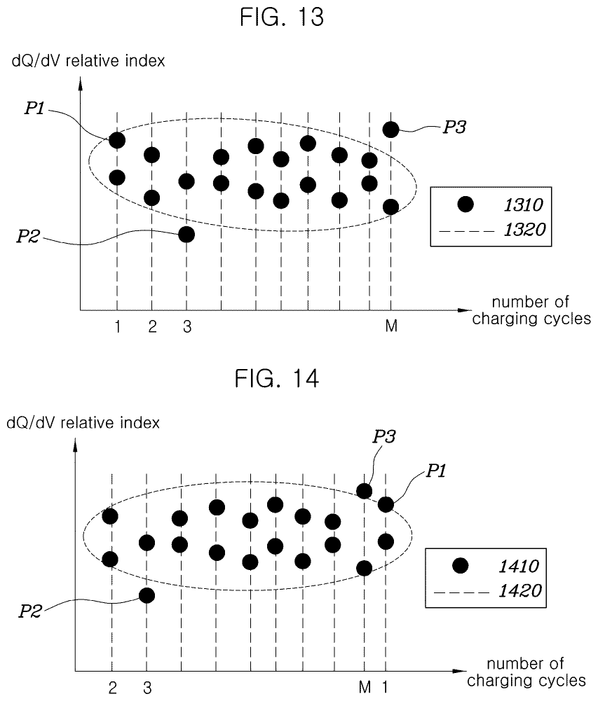

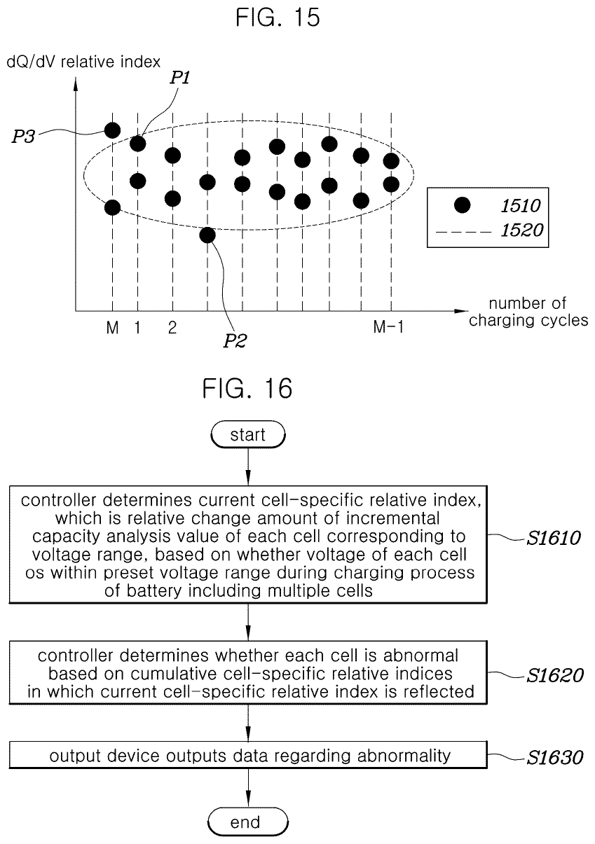

FIG. 13 shows a first data distribution graph 1310 and a first Mahalanobis distance graph 1320 in which the cumulative cell-specific relative indices of the plurality of cells Cell_1, Cell_2, . . . , and Cell_N arranged in ascending order from the first charging cycle are depicted. FIG. 14 shows a second data distribution graph 1410 and a second Mahalanobis distance graph 1420 in which the cumulative cell-specific relative indices of the cells Cell_1, Cell_2, . . . , and Cell_N arranged in ascending order from the second charging cycle are depicted. FIG. 15 shows a third data distribution graph 1510 and a third Mahalanobis distance graph 1520 in which the cumulative cell-specific relative indices of the cells Cell_1, Cell_2, . . . , and Cell_N arranged in ascending order from the M-th charging cycle are depicted, when M charging cycles are recorded in the cumulative cell-specific relative indices.

The controller 220 may generate a plurality of data distributions with different reference charging cycles and may determine the Mahalanobis distance for each of the data distributions.

For example, if M charging cycles are recorded, the controller 220 may generate M data distributions including the first data distribution having the first charging cycle as a reference charging cycle to the M-th data distribution having the M-th charging cycle as a reference charging cycle.

In other words, the controller 220 may generate M data distributions according to different reference charging cycles based on cumulative cell-specific relative indices corresponding to a voltage range, and each data distribution may have data arranged in ascending order from the charging cycle corresponding to the starting point.

For example, if M charging cycles are recorded, the first data distribution 1310 may have data arranged in ascending order from the cumulative cell-specific relative index corresponding to the first charging cycle to the cumulative cell-specific relative index corresponding to the M-th charging cycle, the second data distribution 1410 may have data arranged in ascending order from the cumulative cell-specific relative index corresponding to the second charging cycle to the cumulative cell-specific relative index corresponding to the M-th charging cycle and may have cumulative cell-specific relative indices corresponding to the first charging cycle, and the M-th data distribution 1510 may have data arranged sequentially from the cumulative cell-specific relative index corresponding to the first charging cycle to the cumulative cell-specific relative index corresponding to the (M−1)-th charging cycle in ascending order after the cumulative cell-specific relative index corresponding to the M-th charging cycle.

However, the number of data distributions described above is merely an example, and it is not necessary to generate M data distributions. For example, if M charging cycles are recorded in a range, the controller 220 may generate M/2 data distributions if M is an even number or generate M/2−1 data distributions if M is an odd number and may determine whether each cell is abnormal based on the Mahalanobis distance of each generated data distribution. The controller 220 may determine a cell in which the number of times an outlier is detected exceeds a preset threshold as an abnormal cell based on the plurality of data distributions.

For example, if the first relative index P1 included in the first charging cycle corresponds to the first cell Cell_1, the first relative index P1 is within the first Mahalanobis distance 1320 corresponding to the first data distribution 1310 and within the third Mahalanobis distance 1520 corresponding to the third data distribution 1510 but deviates the second Mahalanobis distance 1420 corresponding to the second data distribution 1410, and thus the controller 220 may determine an outlier of the first cell Cell_1 due to the first relative index P1 as 1.

As another example, if the second relative index P2 included in the third charging cycle corresponds to the second cell Cell_2, the second relative index P2 deviates from the first Mahalanobis distance 1320 corresponding to the first data distribution 1310, the second Mahalanobis distance 1420 corresponding to the second data distribution 1410, and the third Mahalanobis distance 1520 corresponding to the third data distribution 1510, and thus the controller 220 may determine an outlier of the second cell Cell_2 due to the second relative index P2 as 3.

As another example, if the third relative index P3 included in the M-th charging cycle corresponds to the N-th cell Cell_N, the third relative index P3 deviates from the first Mahalanobis distance 1320 corresponding to the first data distribution 1310, the second Mahalanobis distance 1420 corresponding to the second data distribution 1410, and the third Mahalanobis distance 1520 corresponding to the third data distribution 1510, and thus the controller 220 may determine an outlier of the N-th cell Cell_N due to the third relative index P3 as 3.

FIG. 16 is a flowchart illustrating a method of diagnosing abnormality of each cell of a battery according to an embodiment.

Referring to FIG. 16, during a charging process of the battery 100 including a plurality of cells Cell_1, Cell_2, . . . , and Cell_N, the controller 220 may determine a current cell-specific relative index, which is a relative change amount of an incremental capacity analysis value of each of the cells Cell_1, Cell_2, . . . , and Cell_N corresponding to a voltage range, based on whether the voltage of each cell is within a preset voltage range (S1610).

In addition, the controller 220 may determine whether each cell is abnormal based on cumulative cell-specific relative indices in which the current cell-specific relative index has been reflected (S1620).

For example, determining whether each cell is abnormal may include determining, by the controller 220, whether each cell is abnormal based on a previous cell-specific relative index determined at a time point adjacent to a time point when the current cell-specific relative index is determined in the cumulative cell-specific relative indices and the current cell-specific relative index.

As another example, determining whether each cell is abnormal may include determining, by the controller 220, the cell corresponding to the current cell-specific relative index as an abnormal cell if the sign of the value obtained by subtracting the previous cell-specific relative index determined at a time point adjacent to a determination time point of the current cell-specific relative index from the current cell-specific relative index remains constant for a preset number of times.

As another example, determining whether each cell is abnormal may include determining, by the controller 220, whether each cell is abnormal based on the Mahalanobis distance of the cumulative cell-specific relative indices.

In addition, the input/output device 210 may output data regarding abnormality determined by the controller 220 to the outside (S1630).

According to the embodiment of the present disclosure, it is possible to provide a battery cell diagnostic device and a battery cell diagnostic method for determining whether each cell is abnormal based on electrochemical characteristic data acquired during multiple battery cell charging processes. A vehicle including the device is also provided.

In addition, it is possible to provide a battery cell diagnostic device and a battery cell diagnostic method capable of determining whether each cell is abnormal even when only some of a plurality of preset voltage ranges have been passed during a charging process. A vehicle including the device is also provided.

The effects that can be obtained in the present disclosure are not limited to the effects mentioned above, and other effects that are not mentioned can be clearly understood by a person having ordinary knowledge in the technical field to which the present disclosure belongs from the description below.

The above-described present disclosure can be implemented as computer-readable code on a medium in which a program is recorded. The computer-readable medium includes all kinds of recording devices in which data that can be read by a computer system is stored. Examples of the computer-readable medium include a hard disk drive (HDD), a solid state drive (SSD), a silicon disk drive (SDD), a ROM, a RAM, a CD-ROM, a magnetic tape, a floppy disk, an optical data storage device, etc. Therefore, the above detailed description should not be construed as limiting in all aspects but should be considered as illustrative. The scope of the present disclosure should be determined by a reasonable interpretation of the appended claims. All changes within the equivalent scope of the present disclosure are included in the scope of the present disclosure.

What is claimed is:

1. A battery cell diagnosing device comprising:
a controller configured to:
based on whether voltages of a plurality of cells included in a battery are within a preset voltage range in a charge cycle of the battery, determine a current cell-specific relative index, wherein the current cell-specific relative index is a relative change amount of an incremental capacity analysis value of each of the cells corresponding to the voltage range; and
determine whether each cell is abnormal based on cumulative cell-specific relative indices including the current cell-specific relative; and
an output device configured to output data regarding whether each cell is abnormal.

2. The battery cell diagnosing device of claim 1, wherein the controller is further configured to determine the current cell-specific relative index based on i) an average of change amounts of incremental capacity analysis values of the cells and ii) the change amounts of the incremental capacity analysis values of the cells in the voltage range.

3. The battery cell diagnosing device of claim 1, wherein the controller is further configured to determine whether each cell is abnormal based on a slope of a cell-specific trend line determined based on the cumulative cell-specific relative indices.

4. The battery cell diagnosing device of claim 1, wherein the controller is further configured to determine a cell corresponding to the current cell-specific relative index as abnormal based on a sign of a value obtained by subtracting a previous cell-specific relative index determined at a time point, adjacent to a time point when the current cell-specific relative index is determined, from the current cell-specific relative index remaining constant for a preset number of times.

5. The battery cell diagnosing device of claim 4, wherein the controller is further configured to determine a cell corresponding to the current cell-specific relative index as an abnormal cell due to capacity deviation or leakage current based on the sign of the value being continuously positive for a preset number of times.

6. The battery cell diagnosing device of claim 4, wherein the controller is further configured to determine a cell corresponding to the current cell-specific relative index as an abnormal cell in which capacity deterioration progresses based on the sign of the value being continuously negative for a preset number of times.

7. The battery cell diagnosing device of claim 4, wherein the controller is further configured to determine whether a cell corresponding to the current cell-specific relative index s abnormal based on whether the value monotonically decreases or monotonically increases.

8. The battery cell diagnosing device of claim 7, wherein the controller is further configured to determine a cell corresponding to the current cell-specific relative index as an abnormal cell in which deterioration is accelerated based on the value determined as monotonically decreasing or monotonically increasing.

9. The battery cell diagnosing device of claim 1, wherein the controller is further configured to determine whether each cell is abnormal based on a Mahalanobis distance of the cumulative cell-specific relative indices.

10. The battery cell diagnosing device of claim 9, wherein the controller is further configured to:
generate a plurality of data distributions with different charging cycles serving as a basis of the Mahalanobis distance among a plurality of charging cycles considered in determining the cumulative cell-specific relative indices; and
determine the Mahalanobis distance for each of the data distributions.

11. The battery cell diagnosing device of claim 9, wherein the controller is further configured to determine a cell corresponding to cumulative cell-specific relative indices based on a number of data points exceeding the Mahalanobis distance being equal to or greater than a preset threshold number as an abnormal cell.

12. The battery cell diagnosing device of claim 1, wherein the controller is further configured to determine whether each cell is abnormal based on i) a previous cell-specific relative index determined at a time point adjacent to a time point when the current cell-specific relative index is determined in the cumulative cell-specific relative indices and ii) the current cell-specific relative index.

13. The battery cell diagnosing device of claim 12, wherein the controller is further configured to:
determine a threshold based on an average change amount of the cumulative cell-specific relative indices; and
determine whether a cell corresponding to the current cell-specific relative index is abnormal based on whether a value obtained by subtracting the previous cell-specific relative index from the current cell-specific relative index exceeds the threshold.

14. The battery cell diagnosing device of claim 1, wherein the controller is configured to:
determine an abnormality score based on weights corresponding to each of a plurality of algorithms for determining abnormality and a number of data points determined to be abnormal based on the plurality of algorithms; and
determine abnormality based on the abnormality score.

15. The battery cell diagnosing device of claim 1, wherein the preset voltage range is set to a plurality of ranges set including different voltages at peak values of the incremental capacity analysis values, and
wherein the controller is configured to further determine the current cell-specific relative index corresponding to at least one range based on the voltages of the cells being within the at least one of the plurality of ranges in the charging cycle.

16. A method of diagnosing battery cells, the method comprising:
based on whether voltages of a plurality of cells included in a battery are within a preset voltage range in a charge cycle of the battery, determining, by a controller, a current cell-specific relative index, wherein the current cell-specific relative index is a relative change amount of an incremental capacity analysis value of each of the cells corresponding to the voltage range;
determining, by the controller, whether each cell is abnormal based on cumulative cell-specific relative indices including the current cell-specific relative index; and
outputting, by an output device, data regarding whether each cell is abnormal.

17. The method of claim 16, wherein determining whether each cell is abnormal comprises determining, by the controller, whether each cell is abnormal based on i) a previous cell-specific relative index determined at a time point adjacent to a time point when the current cell-specific relative index is determined in the cumulative cell-specific relative indices and ii) the current cell-specific relative index.

18. The method of claim 16, wherein determining whether each cell is abnormal comprises determining, by the controller, a cell corresponding to the current cell-specific relative index as abnormal based on a sign of a value obtained by subtracting a previous cell-specific relative index determined at a time point, adjacent to a time point when the current cell-specific relative index is determined, from the current cell-specific relative index remaining constant for a preset number of times.

19. The method of claim 16, wherein determining whether each cell is abnormal comprises determining, by the controller, whether each cell is abnormal based on a Mahalanobis distance of the cumulative cell-specific relative indices.

20. A vehicle comprising:
a battery including a plurality of cells;
a controller configured to:
based on whether voltages of a plurality of cells included in a battery are within a preset voltage range in a charge cycle of the battery, determine a current cell-specific relative index, wherein the current cell-specific relative index is a relative change amount of an incremental capacity analysis value of each of the cells corresponding to the voltage range; and
determine whether each cell is abnormal based on cumulative cell-specific relative indices including the current cell-specific relative index; and
an output device configured to output data regarding whether each cell is abnormal.
